(19) United States
(12) Patent Application Publication
(10) Pub. No.: US 2022/0220601 A1
(43) Pub. Date: Jul. 14, 2022

(54) PVD COATINGS COMPRISING MULTI-ANION HIGH ENTROPY ALLOY OXY-NITRIDES

(71) Applicant: OERLIKON SURFACE SOLUTIONS AG, PFÄFFIKON, Pfäffikon (CH)

(72) Inventors: Siva Phani Kumar YALAMANCHILI, Sargans (CH); Helmut RUDIGIER, Chur (CH); Doris FOPP-SPORI, Landquart (CH)

(21) Appl. No.: 17/613,065

(22) PCT Filed: May 25, 2020
(86) PCT No.: PCT/EP2020/064441

§ 371 Date: Nov. 21, 2021

(51) Int. Cl. C23C 14/06; C23C 14/35; C23C 14/32

(52) U.S. Cl. CPC C23C 14/0676; C23C 14/325; C23C 14/35

(57) ABSTRACT

Method for producing a coating comprising at least one PVD coating layer, wherein for the production of the at least one PVD coating layer materials from one or more targets are evaporated by using a PVD technique in a coating chamber comprising oxygen and nitrogen as reactive gases, wherein during deposition of the at least one PVD coating layer a multi-anion HEA-oxynitride structure is formed, which comprises a cation lattice formed of five or more elements and an anion lattice formed of two or more elements, wherein if only two elements are present in the anion lattice, they are oxygen and nitrogen.

The present invention relates to a method for producing new HEA coating materials, which exhibit thermal stability at high temperatures as well as to the corresponding new HEA coating materials.

### STATE OF THE ART

High Entropy Alloys are usually called HEA and are an emerging class of materials consisting of at least 5 components, and exhibit an estimated configurational entropy, wherein S conf. >1.4 R and R is known as gas constant. The configurational entropy (S conf.) is estimated using the formula [1] as described below, assuming a random solid solution formation between these components:

$$S conf . = - R {\sum }_{-} ( i = 1 ) ⩓ {nx}_{i} {Inx}_{i} \qquad [ 1 ]$$

where R is the gas constant, xi is the molar fraction of the corresponding element, and n is the total number of constituent elements.

The above equation indicates that the configurational entropy scales with the number of constituents (i.e. S conf. increases when the total number of constituents increases).

On the other hand, when the five different components are mixed together, whether the solid solution formation is favored or not depends on the dynamic balance between the enthalpy of mixing (ΔHₘᵢₓ), and entropy of mixing (ΔSₘᵢₓ), given by the formula [2] as described below. A solid solution of 5 components is favored when the ΔGₘᵢₓ value is the lowest of all the possible configurations.

$$Δ {G}_{mix} = Δ {H}_{mix} - T Δ {S}_{mix} \qquad [ 2 ]$$

where, ΔHₘᵢₓ is the enthalpy of mixing, ΔSₘᵢₓ is the entropy of mixing, and T is the temperature. This means in a high entropy alloy, a positive ΔHₘᵢₓ is overcome by TΔSₘᵢₓ, driven by a high configurational entropy of mixing, to favor solid solution over phase separation.

Based on the above-mentioned thermodynamic principles, Christina M. Rost et al., have reported entropy stabilized oxides at a temperature above 1000° C. using a powder metallurgy route. These entropy stabilized oxides were not synthesized as coatings but as bulk-materials. The powder metallurgy route can be described as following:

MgO(Rs)+Nio(Rs)+CoO(Rs)+Cuo(T)+ZnO(w)--->(Mg,Ni,Co,Cu,Zn)(Rs) [3]

wherein Rs corresponds to Rock Salt, T to Tenorite and W to Wurtzite structures, respectively.

It was reported that the energy penalty caused by the transformation of CuO and ZnO respectively from Tenorite, and Wurtzite structures to Rock salt structure is in the range of 0.1 eV/atom (ΔHₘᵢₓ), which is overcome by the entropy components TΔSₘᵢₓ in formula [2] at a temperature above 900° C.

However, this material system has inherently lower hardness and is thus not suitable for wear resistant applications.

On the other hand, in nitride alloys A. D. Pogrebnjak et al, have reported various High entropy alloy nitrides such as (AlCrMoSiTi)N, (TiZrHfNbTa)N, (AlCrNbSiTiV)N, (TiVCrZrTa)N, (AlCrMoTaTiZr)N which have been deposited in the cubic phase. But the entropy stabilization i.e. if the solid solution is stable up to elevated temperatures e.g. 1100° C. could not be shown.

However, K. Yalamanchili et al have investigated entropy stabilization up to 1100° C. in c-(AlTiVNbCr)N alloy, and reported that at elevated temperature, the balance of (ΔHₘᵢₓ), and TΔSₘᵢₓ has led to

c-(AlTiVNbCr)N-->w-AlN+c-(TiNbVCr)N [4]

These structural changes observed by K. Yalamanchili et al are undesirable, as they are typically associated with undesirable volume changes and simultaneously reduced mechanical properties.

WO 2020/084166 A1 describes a PVD coating process for producing a multifunctional coating structure, wherein the multifunctional coating structure shows phase stability up to high temperatures of 1100° C. The procedure according to the WO 2020/084166 A1 has however the disadvantage of comprising an additional step of a targeted introduction of a controlled precipitate structure into an HEA ceramic matrix which has been produced on a substrate in a first step. This additional step requires additional equipment, such as a laser source or other thermal source, which must be accommodated in the respective coating chamber. This not only increases the cost of producing the coatings, but also minimizes the space available in the coating chamber. In addition, the method according to the WO 2020/084166 A1 is disadvantageously usually only locally limited applicable.

### OBJECTIVE OF THE PRESENT INVENTION

It is an object of the present invention to alleviate or to overcome one or more difficulties related to the prior art. In particular, it is an object of the present invention to provide an efficient, preferably also a simple, fast and cheap, method for producing new HEA coating materials, which show thermal stability at high temperatures, i.e. temperatures of 700° C. or higher, in particular temperatures of 800° C. or higher, more in particular temperatures of 900° C. or higher, e.g. 1000° C. or 1100° C.

### DESCRIPTION OF THE PRESENT INVENTION

In order to overcome these difficulties, the present invention provides a method for producing thermal stable coatings comprising or consisting of multi-anion High Entropy Alloy (HEA) oxy-nitrides.

The inventive method is preferably carried out by producing the inventive coatings by using any PVD (Physical Vapor Deposition) techniques, in particular cathodic arc evaporation, sputtering or HiPIMS. Thus, the present invention relates to new HEA materials synthetized as PVD coatings by using cathodic arc evaporation, sputtering or any other PVD techniques wherein the inventive PVD coatings comprise or consist of multi-anion HEA oxynitrides.

According to the present invention a PVD coating material is produced comprising a cation sublattice designed as multi-principal alloy, formed by at least five elements (e.g. AlTaSiCrTi) and an anion sublattice formed of at least two elements, wherein the at least two elements present in the anion sublattice are nitrogen and oxygen).

The term multi-principal element alloy is used for indicating that all alloy elements are present in a content range between 10 at. % and 40. at %, so that it cannot be considered that one of the elements is present in a dominant quantity. This should be understood as, if no elements are present in a concentration lower than 10 at. % or higher than 40 at. % not any of the elements can be considered having a dominant concentration (e.g. if the cation sublattice has element composition: Al₁₉Ta₂₁Si₁₁Cr₁₁Ti₃₈).

According to a preferred embodiment of the present invention the PVD coating comprises or consists of a multi-principal element alloy comprising TMN, AlN and Si₃N₄, where TM is one or more transition metals and thus TMN is a nitride of TM, AlN is aluminum nitride and Si₃N₄ is silicon nitride, wherein the multi-principal element alloy is formed in cubic phase and produced exhibiting a such anion entropy stabilization, that it enables retaining the cubic phase at temperatures of 700° C. or higher, preferably at temperatures of 800° C. or higher, more preferably at temperatures of 900° C. or higher, e.g. after annealing up to 1100° C., for some application preferably up to temperatures >1100° C.

Thus, in a first aspect of the present invention disclosed is a method for producing a coating comprising at least one PVD coating layer, wherein for the production of the at least one PVD coating layer materials from one or more targets are evaporated by using a PVD technique in a coating chamber comprising oxygen and nitrogen as reactive gases, wherein during deposition of the at least one PVD coating layer a multi-anion HEA-oxynitride structure is formed, which comprises a cation lattice formed of five or more elements and an anion lattice formed of two or more elements, wherein if only two elements are present in the anion lattice, they are oxygen and nitrogen.

The term multi-anion HEA-oxynitride structure is preferably understood in the context of the invention as a structure which, in addition to High Entropy Alloys building a cation sublattice, comprises an oxynitride anion sub lattice formed of at least two atoms, i.e. the at least two atoms are oxygen (O) and nitrogen (N). It is thus understood that the oxynitride sub lattice of the multi-anion HEA oxynitride structure may also comprise more than two atoms, for example more than 10, in particular more than 15 atoms. To provide a suitable reactive atmosphere for generation of the multifunctional coating structure according to the invention, it may, for example, be provided that a constant nitrogen partial pressure of preferably at least 2 Pa, in particular at least 5 Pa, is provided. A continuous quantity of oxygen can then be added to this partial pressure, preferably with an oxygen flow of at least 10 sccm, preferably at least 30 sccm.

The inventive PVD coatings produced by using the inventive method can be used for example as wear resistant coatings or as decorative coatings or also as any other kind of functional coatings. In the context of the present invention the term “functional coatings” is used for referring to coatings deposited on substrate surfaces for providing the substrate surfaces with one or more specific functions.

The coating structure according to the invention is preferably generated in one step by depositing the evaporated target material (from one or more targets having same or different element composition) on the substrate. Hereby, without needing additional steps like a thermal post-treatment for generation of the inventive coating. In other words, according to the invention the PVD coating having presenting a multi-anion HEA oxynitride can be generated by reactive deposition of the evaporated target material on a substrate placed in a vacuum chamber comprising at least oxygen gas and nitrogen gas as reactive gases. That does not necessarily mean that no additional steps can be carried out to further improve and/or adapt further properties of the inventive coating structures produced according to the invention, like depositing a further layer as adhesion layer or as a top layer.

As explained above, a sputtering technique, in particular HiPIMS (High-power impulse Magnetron Sputtering) or an ARC PVD (cathodic arc evaporation PVD) process, can be used as the PVD coating process for producing the inventive coatings.

Furthermore, in another example of the first aspect, the material of the one or more targets is selected comprising the five or more elements that are to be present in the cation lattice.

In another example of the first aspect, the material of the one or more targets comprises at least one transition metal of the 4th, 5th or 6th group of the periodic table of the elements and at least one of the elements Al, Si, B, wherein preferably Al and Si are included.

In another example of the first aspect, the coating structure is deposited on a substrate by applying a negative bias voltage to the substrate during the coating process, wherein the bias voltage being <200 V, preferably <150 V, in particular <120 V.

In another example of the first aspect, at least three different target materials are evaporated and deposited on the substrate, preferably simultaneously.

In another example of the first aspect, one or more of the targets used in the coating process comprise target material to be evaporated for forming the coating as a result of a reaction with the reactive gases present in the vacuum chamber, said target material comprising at least a sum of five elements, which can be selected from:
the transition metals of the 4th, 5th or 6th group of the periodic table of the elements, and
the elements Al, Si and B.

A controlled addition of Al, Si or Ta can be thereby preferably carried out in the form of their nitrides, it means that Al can be added forming AlN (aluminum nitride), Si can be added forming SiN (silicon nitride) and Ta can be added as TaN (tantalum nitride). In doing so, it is possible to obtain that:
the addition of AlN, TaN and/or SiN leads to a high oxidation resistance due to sluggish diffusion of the chemical components in the coating, and
the addition of AlN and/or SiN leads to a high fracture resistance, as the local atomic distortions causes crack branching.

Preferably, the substrate temperature during the production of the coating structure is between 100° C. and 400° C., in some cases more preferably between 150° C. and 300° C., in particular between 200° C. and 250° C.

In a second aspect, a coating structure produced by using the inventive process as described above is provided by the present invention, wherein the coating comprises a multi-anion HEA-oxynitride structure, wherein the High Entropy Alloy in the HEA-oxynitride structure comprise at least one transition metal of the of the 4th, 5th or 6th group of the periodic table of the elements and at least one of the elements Al, Si, B, preferably Al and Si and optionally B.

One of the key aspects of inventive HEA (AlTiTaCrSi) oxynitride is that cubic solid solution is retained after annealed to 1100° C. or even beyond 1100° C. It is to be noted that for their respective quasi-binary alloys after the elevated temperature anneals, the immiscible components are separated into their stable crystal structures, such as AlN in wurtzite structure, TaN in Hexagonal structure, and Si₃N₄ in Trigonal structure. More over CrN becomes to hexagonal Cr₂N. Surprisingly, in the inventive HEA oxy-nitride suppresses the above undesirable phase changes, but retains a single solid solution of cubic phase.

Preferably the High Entropy Alloy in the HEA-oxynitride structure of the coating comprises in total at least five elements of a transition metal of the 4th, 5th or 6th group of the periodic table of the elements and one of the elements Al, Si, B. It should be understood that in this preferred design with at least five elements in total, at least one element must be a transition metal of the 4th, 5th or 6th group of the periodic table of the elements, and at least one further element must be one element selected from Al, Si and B.

Advantageously, the invention may provide that the inventive coating structure comprises an anion sublattice comprising more than two atoms, preferably more than 5 atoms, in particular more than 10 atoms. With regard to a pronounced structural reinforcement, a multi-anion oxynitride structure of O20N35 in particular can be provided, i.e. in addition to a HEA sub lattice of five elements comprising the elements Al, Ta, Si, Cr and Ti.

It may also be beneficial, if the inventive coating structure is formed comprising an multi-anion HEA-oxynitride structure, whose phase is stable up to a temperature of 1100° C., or up to a temperature beyond 1100° C. A phase stability hereby goes along with a stable hardness up to the corresponding elevated temperatures.

For attaining a better stabilization of the cation sublattice, it may be preferred that the inventive multifunctional coating structure is produced by selecting the HEA elements of the cation sublattice such that the structure has a lattice distortion of at least 5%, preferably a lattice distortion of at least 10%, in particular a lattice distortion of at least 20%.

In another example of the second aspect, the layer thickness of the coating structure is less than 8 μm and more than 500 nm.

In another example of the second aspect, the coating structure is formed in the form of a multilayer coating, wherein the total thickness of the multi-layer coating is more than 1 μm, preferably more than 2 μm, in particular more than 5 μm.

In a third aspect of the present in invention, the use of the inventive coating, preferably as a functional coating, particularly for wear resistant coatings or decorative coatings, is disclosed.

The invention will now be described in more details based on examples and with the help of figures.

### DETAILED DESCRIPTION

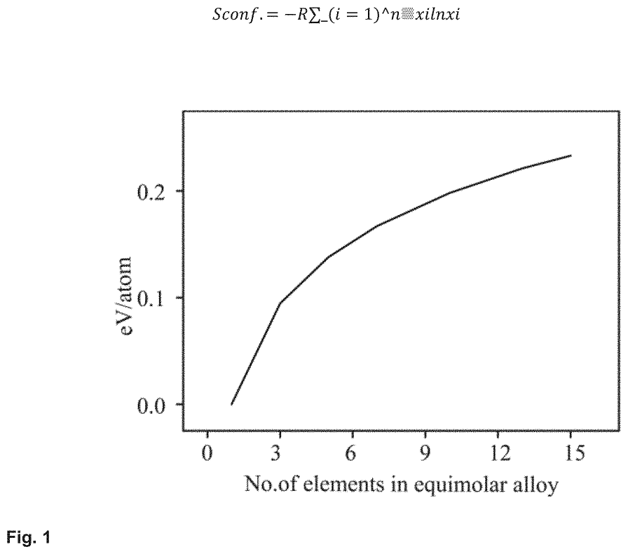

FIG. 1 shows the calculated configurational entropy of mixing (at 1000 K), as a function of number of components in an equimolar alloy,

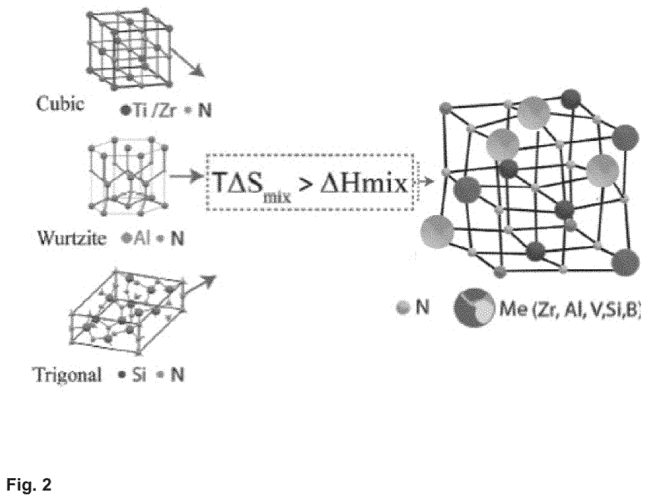

FIG. 2 shows the graphical representation of formation of cubic phase consisting of TMN, AlN, and Si₃N₄, enabled by entropy stabilization,

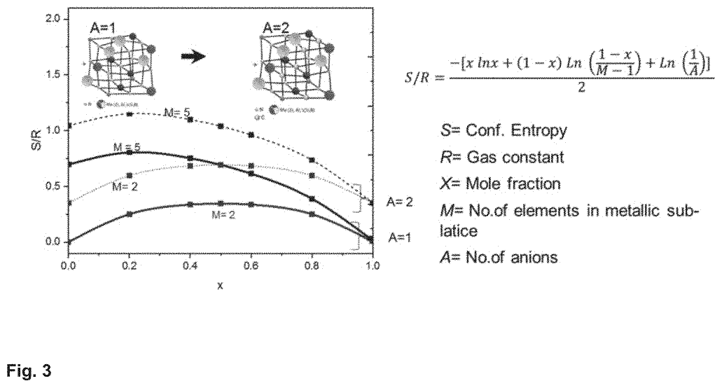

FIG. 3 shows the estimated S/R values for alloys consisting of one anion, and two anion sub lattice with two and five elements in the metallic sub lattice,

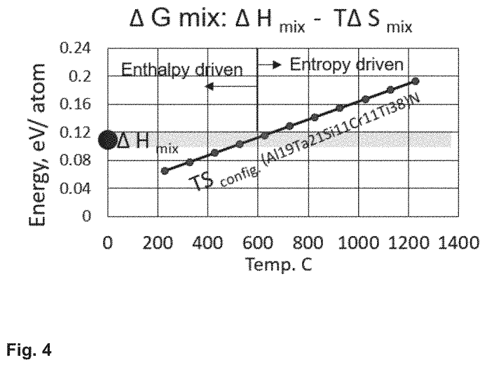

FIG. 4 shows the estimated ΔHₘᵢₓ, and ΔTₛ mix for the (AlTaSiCrTi)N alloy with respect to their binaries,

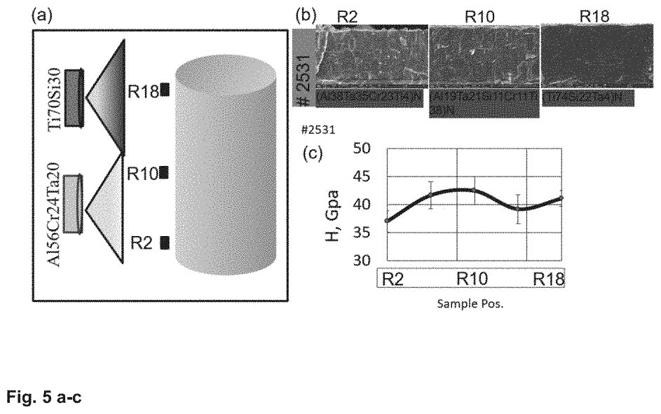

FIG. 5a shows the schematic set up used to grow HEA nitrides and oxi-nitrides using industrial scale reactive arc deposition system,

FIG. 5b shows SEM image of fractured-cross section of coating at bottom (R2), middle (R10), and top (R18) positions,

FIG. 5c shows hardness evolution as a function of substrate position,

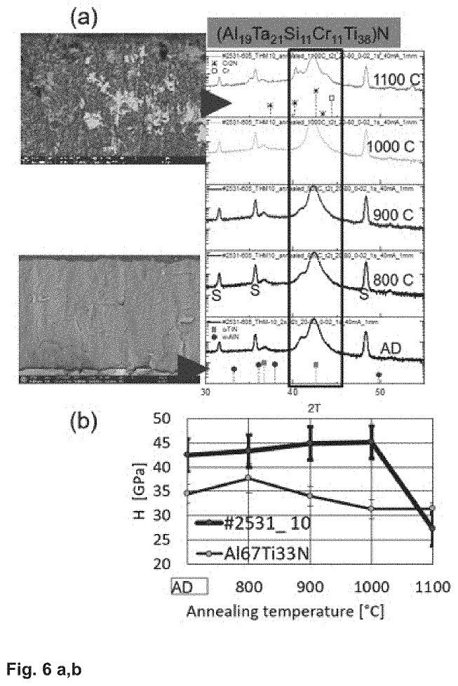

FIG. 6a shows XRD pattern of (Al₁₉Ta₂₁Si₁₁Cr₁₁Ti₃₈)N of As-deposited (AD), and after elevated temperature anneals,

FIG. 6b shows H evolution of the (Al₁₉Ta₂₁Si₁₁Cr₁₁Ti₃₈)N as a function of annealing temperature, and compared to bench marked Al₆₇Ti₃₃N coating,

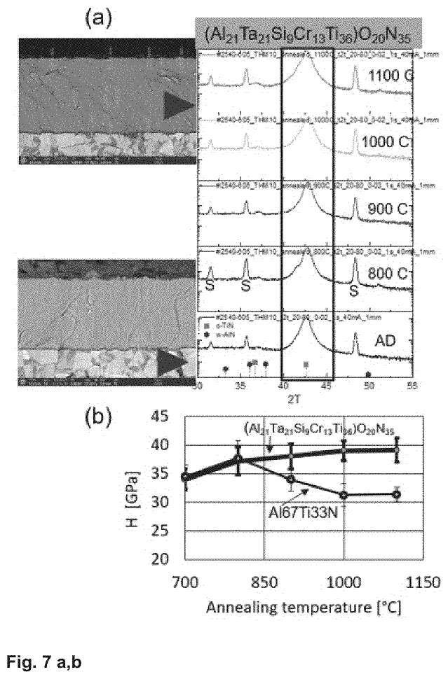

FIG. 7a shows XRD pattern of (Al₂₁Ta₂₁Si₉Cr₁₃Ti₃₆)O₂₀N₃₅ of As-deposited (AD), and after elevated temperature anneals,

FIG. 7b shows H evolution of the (Al₂₁Ta₂₁Si₉Cr₁₃Ti₃₆)O₂₀N₃₅ as a function of annealing temperature, and compared to bench marked Al₆₇Ti₃₃N coating,

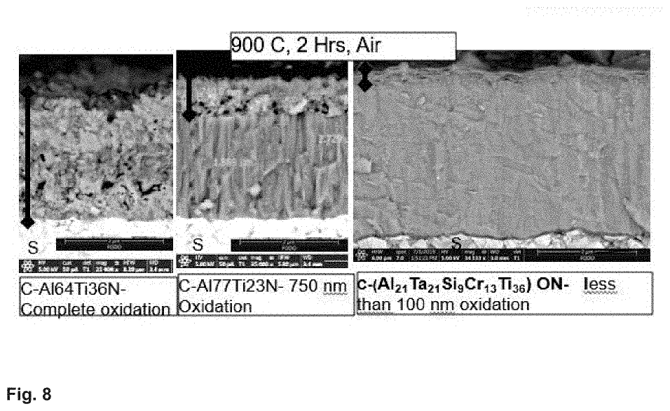

FIG. 8 shows a cross-sectional SEM image of the coated substrate after subjecting to oxidation at 900° C. for 2 Hrs in ambient atmosphere.

FIG. 1 shows the calculated configurational entropy of mixing (at 1000 K), as a function of number of components in an equimolar alloy. The above equation indicates that the configurational entropy scales with the number of constituents.

FIG. 2 shows a graphical representation of formation of cubic phase consisting of TMN, AlN, and Si₃N₄, enabled by entropy stabilization. As already mentioned above, an objective of the present invention is to provide new materials that can preferably be produced as coating materials (more preferably as PVD coatings). These coatings may also comprise alloys of TMN, AlN, and Si₃N₄ formed in cubic phase that can retain its phase stability after elevated temperature annealing up to 1100° C., enabled by entropy stabilization, as graphically shown in FIG. 2. This example indicates that the previously mentioned entropy stabilization effect, there by retaining the cubic solid solution consisting of non-iso structural components under thermodynamic equilibrium conditions such as elevated temperature anneals of 1100° C. may not achieved by random choice of alloying elements.

In a further aspect of the invention, due to entropy stabilization, the inventive alloy design also considers choice of elements with a high difference in the atomic sizes, thereby to induce a lattice distortion as shown in FIG. 2. The induced lattice distortion strengthens the alloy, and hampers the diffusivity of the alloy e.g. in the inventive alloy, mixture of Ta with an ionic radius of 170 pm, and Si with an ionic radius of 111 pm creates a lattice distortion approximately about 20% distortion in the lattice very locally.

FIG. 3 shows estimated S/R values for alloys consisting of one anion, and two anion sub lattice with two and five elements in the metallic sub lattice.

As already mentioned, an objective of the present invention is attained by providing new materials produced preferably as PVD coatings comprising or consisting of multi-anion High Entropy Alloy Oxy-Nitrides.

The new materials produced according to the present invention particularly differ from the state of the art at least in following aspects:

1) Design of Multi-principal element alloy with 5 elements in the cation sublattice with 2 or more anion sub-lattice i,e, nitride, and oxide sub-lattice as an example. FIG. 3 compares the variation of S/R value for an alloy with one anion to two anions while having 5 elements in metallic sub-lattice. Further increase in S/R value with more anions.

2) Choice of metallic elements includes group 4, 5, and 6 elements with controlled addition of Al, Si, and optionally of B so to make sure that the high ΔH mix value is overtaken by TΔSₘᵢₓ at finite temperatures of about 900° C.

FIG. 4 shows an estimated Δ Hₘᵢₓ, and Δ Tₛ mix for the (AlTaSiCrTi)N alloy with respect to their binaries. Note that entropy overtakes enthalpy component at Temp of about 700° C. (more exactly ca. 650° C. or a values between 600° c. and 700° C.). In particular, FIG. 4 shows an estimated balance for the alloy of (Al₁₉Ta₂₁Si₁₁Cr₁₁Ti₃₈)N. ΔHₘᵢₓ values were taken from published literature, and TΔSₘᵢₓ values were estimated from the formula 1. The graphic represents only two configurations, i.e cubic solid solution with respect to their binaries. But in principal this consideration should include all other configurations or decomposition path ways. This consideration is a necessary criterion, but not sufficient criterion.

FIG. 4 indicates that a likely entropy stabilization for (Al₁₉Ta₂₁Si₁₁Cr₁₁Ti₃₈)N alloy at Temp above ˜700 C. Also in the consideration only one anion lattice is presented, and from the previously description it is known that 2 anion sublattice alloy i.e. (Al₁₉Ta₂₁Si₁₁Cr₁₁Ti₃₈)ON should favor the enhanced entropy stabilization compared to nitride alloy.

FIG. 5a shows the schematic set up used to grow HEA nitrides and oxi-nitrides using industrial scale reactive arc deposition system. The example coating of (Al₁₉Ta₂₁Si₁₁Cr₁₁Ti₃₈)N is grown in combinatorial approach using the targets of Al₅₆Cr₂₄Ta₂₀ at bottom (R2), and Ti₇₀Si₃₀ at top (R18).

FIG. 5b shows a SEM image of fractured-cross section of coating at bottom (R2), middle (R10), and Top (R18) positions. The composition of the coatings measured by EDS is indicated in the annotation of FIG. 5b. The targets are arc discharged in N₂ p.partial pressure of 5 Pa, and the resultant coating compostions measured by EDS and the coating fractured SEM micro graph shown is shown in FIG. 5b. In this configuration a High entropy alloy of (Al₁₉Ta₂₁Si₁₁Cr₁₁Ti₃₈)N is synthesized in the middle of the substrate holder at position R10.

FIG. 5c shows hardness evolution as a function of substrate position.

Apart from the core of the invention as described above, there are additional technical measures which lead to preferred embodiments of the invention. For example, following additional technical measures:

1) Multi-principal element oxy-nitride alloy consisting of AlN, TaN and SiN will display a high oxidation resistance due to sluggish diffusion of the chemical components in the coating.

2) Multi-principal element oxy-nitride alloy comprising AlN, and SiN will display a high fracture resistance, as the local atomic distortions causes crack branching.

3) Controlled formation of AlN, and SiN is motivated next to enable high oxidation resistance, high temperature properties

4) Multi-principal element oxy-nitride alloy comprising AlN, and SiN, with entropically stabilized cubic phase, without causing phase separation at temperatures above 800° C., more preferably of 900° C. or above 900° C., e.g. 1100° C. This high temperature cubic phase stability results in stable hardness up to elevated temperature annealing of 1100° C. and beyond.

FIG. 6a shows XRD pattern of (Al₁₉Ta₂₁Si₁₁Cr₁₁Ti₃₈)N of As-deposited (AD), and after elevated temperature anneals. The SEM images in the back-scattering contrast of the coating in AD, and after annealing to 1100° C. is complemented to XRD. The coating form pos 10 with a composition of (Al₁₉Ta₂₁Si₁₁Cr₁₁Ti₃₈)N is subjected to vacuum annealing up to 1100° C. FIG. 6a presents the structural evolution measured by XRD, complemented with fractured cross-section of the coating in SEM back scattered mode.

XRD image shows that the cubic solid solution of (Al₁₉Ta₂₁Si₁₁Cr₁₁Ti₃₈)N is thermally stable up to 1000 C. But at 1100 C, this coating shows precipitation of Cr₂N, and Cr. The decomposition is also clearly visible in the SEM images of the coating after annealing to 1100 C.

FIG. 6b shows H evolution of the (Al₁₉Ta₂₁Si₁₁Cr₁₁Ti₃₈)N as a function of annealing temperature, and compared to bench marked Al₆₇Ti₃₃N coating. Note that the coating precipitates Cr₂N, and Cr after annealing to 1100° C. that leads to hardness drop. At temperatures above 1000 C, the alloy (Al₁₉Ta₂₁Si₁₁Cr₁₁Ti₃₈)N display a steep hardness drop associated with the phase decomposition.

Using the above mentioned description of multi-anion entropy stabilization, (Al₂₁Ta₂₁Si₉Cr₁₃Ti₃₆)O₂₀N₃₅ coatings were grown with Oxygen flow of 30 sccm using the similar deposition conditions. The Oxi-nitride coating thermal stability is also investigated as shown in FIG. 7.

FIG. 7a shows XRD pattern of (Al₂₁Ta₂₁Si₉Cr₁₃Ti₃₆)O₂₀N₃₅ of As-deposited (AD), and after elevated temperature anneals. The SEM images in the back-scattering contrast of the coating in AD, and after annealing to 1100° C. is complemented to XRD.

FIG. 7b shows H evolution of the (Al₂₁Ta₂₁Si₉Cr₁₃Ti₃₆)O₂₀N₃₅ as a function of annealing temperature, and compared to bench marked Al₆₇Ti₃₃N coating. Note that surprisingly this coating shows a thermally stable solid solution at least up to 1100° C., there by a stable solid solution.

Surprisingly, the XRD shows that the cubic solid solution is stable up to annealing temperatures of 1100° C. which is not the case in Nitride alloy with comparable composition in the metallic sub-lattice. The SEM images shows a similar grey scale image for the as-deposited and after annealing to 1100° C., complementing the XRD results.

A higher thermal stability, and a stable hardness behavior of the alloy (Al₂₁Ta₂₁Si₉Cr₁₃Ti₃₆)O₂₀N₃₅ is likely by entropy stabilization thus offers as an example to design a thermally stable TM-Al—Si—ON multi-principal alloy in a wide compositional range. The compositional range includes Group 4, 5, and 6 elements with Al, Si, and B

FIG. 8 shows a cross-sectional SEM image of the coated substrate after subjecting to oxidation at 900° C. for 2 Hrs in ambient atmosphere. The inventive coating oxidation resistance of cubic-(Al₂₁Ta₂₁Si₉Cr₁₃Ti₃₆)ON is compared with industrial standard coatings of cubic Al₆₄Ti₃₆N, and cubic Al₇₇Ti₂₃N.

Surprisingly, even though the inventive alloy has lower Al concentration of 21 at. %, the oxidation resistance is significantly higher the current standard Al-rich AlTiN coatings as shown in FIG. 8. Note that the oxide layer thickness is 3000 nm, 740 nm, and less than 100 nm respectively for cubic Al₆₄Ti₃₆N, cubic Al₇₇Ti₂₃N and inventive high entropy oxy-nitride alloy.

1. A method for producing a coating comprising at least one PVD coating layer, wherein for the production of the at least one PVD coating layer:
materials from one or more targets are evaporated by using a PVD technique in a coating chamber comprising oxygen and nitrogen as reactive gases, wherein:
during deposition of the at least one PVD coating layer a multi-anion HEA-oxynitride structure is formed, which comprises a cation lattice formed of five or more elements and an anion lattice formed of two or more elements, wherein if only two elements are present in the anion lattice, they are oxygen and nitrogen.

2. The method according to claim 1,
wherein the PVD technique is a magnetron sputtering technique.

3. The method according to claim 1,
wherein the material of the one or more targets is selected comprising the five or more elements that are to be present in the cation lattice.

4. The method according to claim 1,
wherein the material of the one or more targets comprises at least one transition metal of the 4th, 5th or 6th group of the periodic table of the elements and at least one of the elements Al, Si, B.

5. The method according to claim 1,
wherein the coating is deposited on a substrate by applying a negative bias voltage to the substrate during the coating process, wherein the bias voltage being <200 V.

6. The method according to claim 1,
wherein at least three targets are evaporated and deposited on the substrate.

7. The method according to one of the preceding claim 1,
wherein the evaporated and deposited target material comprises at least a sum of five elements of a transition metal of the 4th, 5th or 6th group of the periodic table of the elements and the elements Al, Si, B.

8. The method according to claim 1,
wherein the substrate temperature during the production of the coating is between 100° C. and 400° C.

9. A coating, obtainable by using a method for producing a coating comprising at least one PVD coating layer, wherein for the production of the at least one PVD coating layer:
materials from one or more targets are evaporated by using a PVD technique in a coating chamber comprising oxygen and nitrogen as reactive gases, wherein:
during deposition of the at least one PVD coating layer a multi-anion HEA-oxynitride structure is formed, which comprises a cation lattice formed of five or more elements and an anion lattice formed of two or more elements, wherein if only two elements are present in the anion lattice, they are oxygen and nitrogen, comprising:
a multi-anion HEA-oxynitride structure,
wherein the High Entropy Alloy in the HEA-oxynitride structure comprise at least one transition metal of the of the 4th, 5th or 6th group of the periodic table of the elements and at least one of the elements Al, Si, B.

10. The coating according to claim 9,
wherein the High Entropy Alloy in the HEA-oxynitride structure comprises at least in total at least five elements of a transition metal of the 4th, 5th or 6th group of the periodic table of the elements and one of the elements Al, Si, B.

11. The coating according to claim 9, wherein the anion sublattice comprises more than two atoms.

12. The coating according to claim 9, wherein the multi-anion HEA-oxynitride structure is phase stable up to a temperature of 1100° C.

13. The coating according to claim 9, wherein the HEA elements of the cation sublattice are selected such that the structure has a lattice distortion of at least 5%.

14. The coating according to claim 9, wherein the layer thickness of the coating structure is less than 8 μm and more than 500 nm.

15. The coating according to claim 9,
wherein the coating structure is formed in the form of a multi-layer coating, wherein the total thickness of the multi-layer coating is more than 1 μm.

16. A use of coating obtainable by using a method for producing a coating comprising at least one PVD coating layer, wherein for the production of the at least one PVD coating layer:
materials from one or more targets are evaporated by using a PVD technique in a coating chamber comprising oxygen and nitrogen as reactive gases, wherein:
during deposition of the at least one PVD coating layer a multi-anion HEA-oxynitride structure is formed, which comprises a cation lattice formed of five or more elements and an anion lattice formed of two or more elements, wherein if only two elements are present in the anion lattice, they are oxygen and nitrogen, comprising:
a multi-anion HEA-oxynitride structure,
wherein the High Entropy Alloy in the HEA-oxynitride structure comprise at least one transition metal of the of the 4th, 5th or 6th group of the periodic table of the elements and at least one of the elements Al, Si, B as functional coating.

17. The method according to claim 2,
wherein the PVD technique is HiPIMS or a cathodic ARC PVD technique.

18. The method according to claim 4,
wherein Al and Si are included.

19. The method according to claim 6,
wherein at least three targets simultaneously evaporated and deposited.

20. The coating according to claim 12,
wherein the multi-anion HEA-oxynitride structure is phase stable up to a temperature beyond 1100° C.
